(19) United States
(12) Patent Application Publication
(10) Pub. No.: US 2015/0035174 A1
(43) Pub. Date: Feb. 5, 2015

(54) SEMICONDUCTOR DEVICE

(71) Applicant: KABUSHIKI KAISHA TOSHIBA, Minato-ku (JP)

(72) Inventors: Shinya OHASHI, Kamakura-shi (JP); Takashi OKADA, Yokohama-shi (JP)

(73) Assignee: KABUSHIKI KAISHA TOSHIBA, Minato-ku (JP)

(21) Appl. No.: 14/155,719

(22) Filed: Jan. 15, 2014

Related U.S. Application Data
(60) Provisional application No. 61/861,459, filed on Aug. 2, 2013.

(51) Int. Cl. H01L 23/58; H01L 25/065

(52) U.S. Cl. CPC H01L 23/58; H01L 25/0655
USPC 257/784; 257/787

(57) ABSTRACT

According to one embodiment, a semiconductor device includes a first component that generates heat when used, a second component, and a sealing portion. The sealing portion includes a first region and a second region. The first region covers the first component. The second region is thermally divided from the first region and covers the second component.

### CROSS-REFERENCE TO RELATED APPLICATIONS

This application claims the benefit of U.S. Provisional Application No. 61/861,459, filed Aug. 2, 2013, the entire contents of which are incorporated herein by reference.

### FIELD

Embodiments described herein relate generally to semiconductor devices.

### BACKGROUND

Semiconductor devices including a sealing portion covering a plurality of components are provided.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary perspective view illustrating a semiconductor device and an external device according to a first embodiment;

FIG. 2 is an exemplary plan view illustrating an inside of the semiconductor device shown in FIG. 1;

FIG. 3 is an exemplary plan view illustrating a top surface and an undersurface of a board module shown in FIG. 2;

FIG. 4 is an exemplary diagram illustrating the board module shown in FIG. 3;

FIG. 5 is an exemplary diagram illustrating the board module according to a second embodiment;

FIG. 6 is an exemplary diagram illustrating the board module according to a third embodiment;

FIG. 7 is an exemplary diagram illustrating the board module according to a fourth embodiment;

FIG. 8 is an exemplary plan view illustrating the semiconductor device according to a fifth embodiment;

FIG. 9 is an exemplary perspective view partially exploding and illustrating the semiconductor device according to a sixth embodiment;

FIG. 10 is an exemplary plan view illustrating the board module shown in FIG. 9; and

FIG. 11 is an exemplary plan view illustrating the semiconductor device according to a seventh embodiment.

### DETAILED DESCRIPTION

Various embodiments will be described hereinafter with reference to the accompanying drawings.

In general, according to one embodiment, a semiconductor device comprises a first component that generates heat when used, a second component, and a sealing portion. The sealing portion comprises a first region and a second region. The first region covers the first component. The second region is thermally divided from the first region and covers the second component.

In this specification, some components are expressed by two or more terms. Those terms are just examples. Those components may be further expressed by another or other terms. And the other components which are not expressed by two or more terms may be expressed by another or other terms.

The drawings are schematically illustrated. In the drawings, in some cases, the relationship between a thickness and planar dimensions or the scale of the thickness of each layer may be different from the actual relationship or scale. In addition, in the drawings, components may have different dimensions or scales.

### First Embodiment

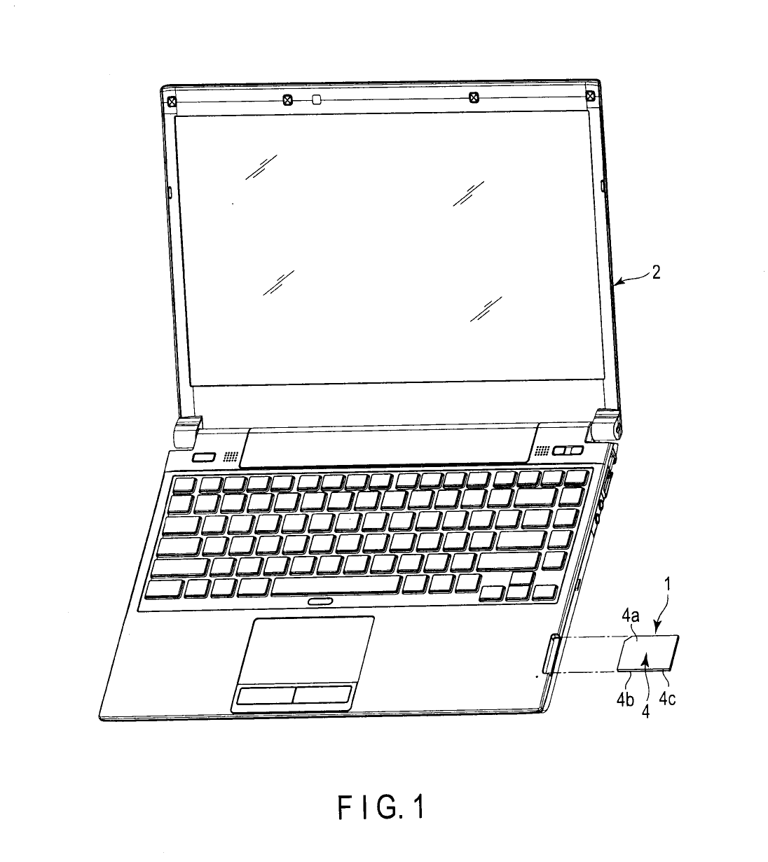

FIGS. 1 to 4 show a semiconductor device 1 according to the first embodiment. The semiconductor device 1 according to the present embodiment is, for example, a semiconductor storage device and an example thereof is an SD memory card (trademark).

FIG. 1 is a perspective view showing the semiconductor device 1 and an external device 2 (e.g., a host apparatus) to which the semiconductor device 1 is connected. For example, various electronic devices (e.g., information processing apparatuses) are applicable as the external device 2 and may be, for example, a portable computer, tablet terminal, digital camera, video camera, or a server connected to a network. The external device 2 performs data access control on the semiconductor device 1 and performs writing, reading, and erasure of data of the semiconductor device 1 by sending, for example, a write request, a read request, and an erase request to the semiconductor device 1 respectively. The external device 2 also provides various power supplies to the semiconductor device 1.

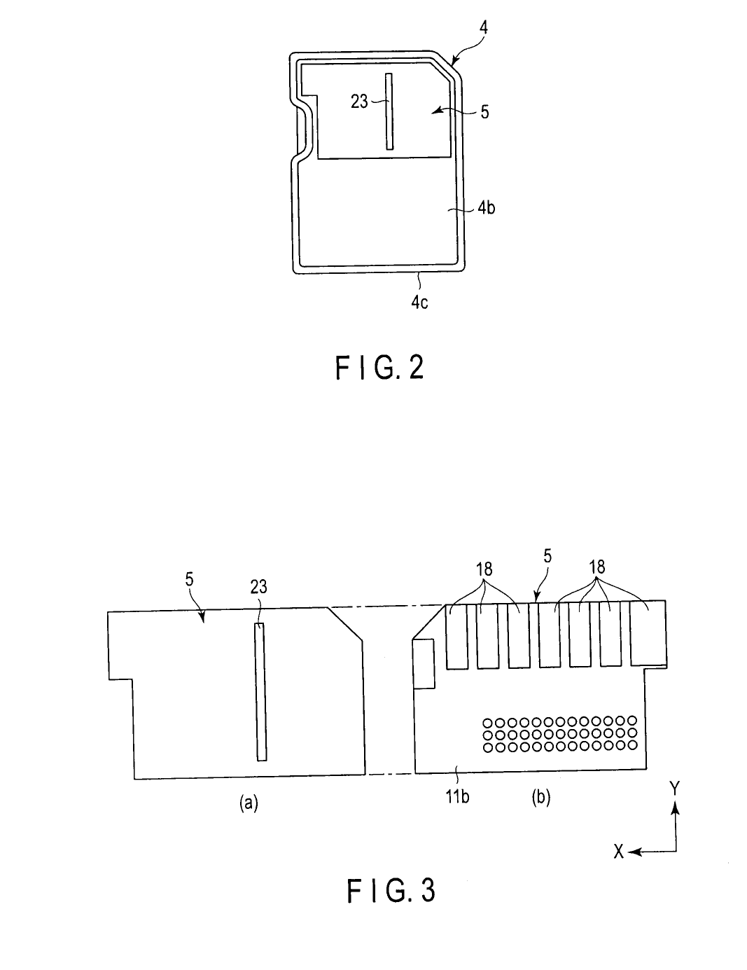

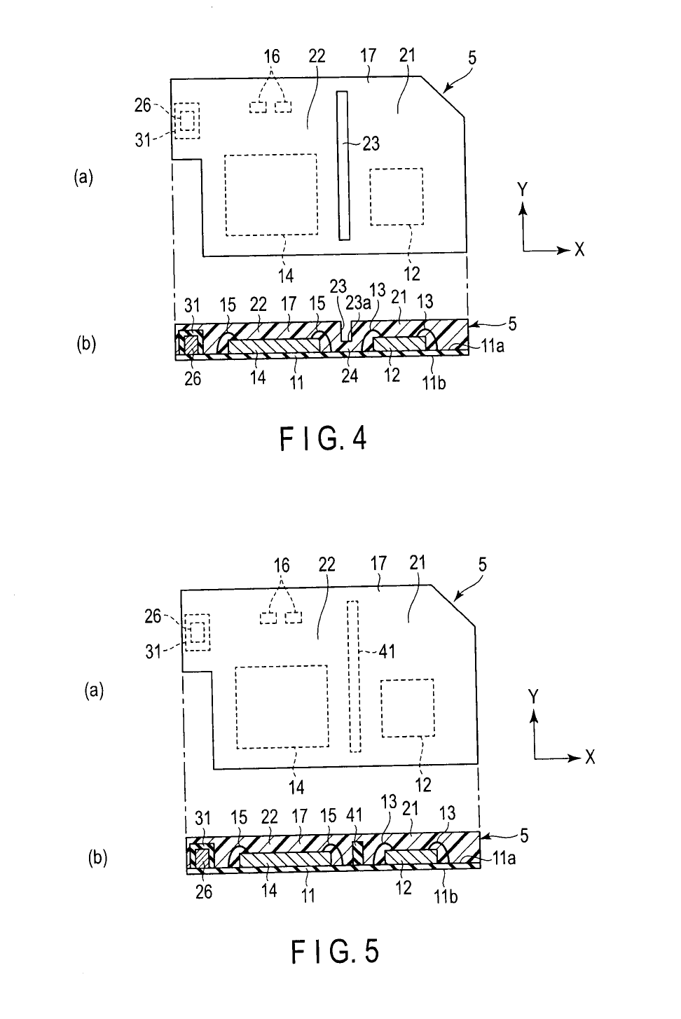

FIGS. 2 to 4 show the semiconductor device 1 according to the present embodiment in detail. FIG. 2 is a plan view illustrating the inside of the semiconductor device 1 shown in FIG. 1. FIG. 3 is a plan view of a board module 5 shown in FIG. 2, (a) of FIG. 3 is a top view thereof and (b) of FIG. 3 is a bottom view thereof. FIG. 4 is a diagram showing the board module 5 shown in FIG. 3, (a) of FIG. 4 is a plan view thereof and (b) of FIG. 4 is a sectional view thereof.

As shown in FIG. 2, the semiconductor device 1 includes a housing 4 and the board module 5 accommodated in the housing 4. The housing 4 (i.e., a case, outer hull, or protection portion) has, for example, a flat box shape corresponding to the SD memory card standard.

The housing 4 is made of, for example, synthetic resin. As shown in FIGS. 1 and 2, the housing 4 includes a first wall 4a, a second wall 4b, and a third wall 4c. The first wall 4a and the second wall 4bextend two-dimensionally parallel to each other. The third wall 4c extends in a direction crossing (e.g., substantially perpendicular to) the first wall 4a and the second wall 4b and connects a circumference of the first wall 4a and a circumference of the second wall 4b.

As shown in FIGS. 3 and 4, the board module 5 is of the SiP (system in package) type and a plurality of semiconductor chips is sealed in one package. That is, the board module 5 is a package component containing the plurality of semiconductor chips. The board module 5 is, for example, substantially half as large as the housing 4, but is not limited to such an example.

More specifically, the board module 5 includes a board 11 (substrate), a controller chip 12, a first bonding wire 13, a semiconductor memory chip 14, a second bonding wire 15, an electronic component 16, a molding resin 17, and a plurality of terminals 18.

The board 11 (e.g., a circuit board or printed board) has a substantially rectangular plate shape and extends substantially in parallel with the first wall 4a and the second wall 4b of the housing 4. The board 11 includes a wiring pattern and has a first surface 11a and a second surface 11b. The second surface 11b is positioned on the opposite side of the first surface 11a.

The controller chip 12 (i.e., a controller, controller component, first component, or first semiconductor component) is mounted on the first surface 11a of the board 11. A pad to which the first bonding wire 13 is connected is provided on the first surface 11a of the board 11. The first bonding wire 13 extends between the first surface 11a of the board 11 and the controller chip 12. The controller chip 12 is electrically connected to the board 11 via the first bonding wire 13.

The controller chip 12 is electrically connected to the semiconductor memory chip 14 via a wiring pattern of the board 11. The controller chip 12 controls the operation of, for example, the semiconductor device 1 collectively. The controller chip 12 exercises control (e.g., access control) to the semiconductor memory chip 14.

That is, the controller chip 12 controls writing, holding, reading, and erasure of data with respect to the semiconductor memory chip 14. The controller chip 12 is an example of “heating components”. The controller chip 12 generates heat when used and becomes hotter than the semiconductor memory chip 14. Incidentally, the “first component” may be a semiconductor component other than the controller chip.

The semiconductor memory chip 14 (i.e., a semiconductor chip, semiconductor component, second component, or second semiconductor component) is, for example, any memory chip (i.e., a memory component) and, for example, a NAND flash memory. Incidentally, the “second component” may be a semiconductor component other than the memory chip.

The semiconductor memory chip 14 is mounted on the first surface 11a of the board 11. A pad to which the second bonding wire 15 is connected is provided on the first surface 11a of the board 11. The second bonding wire 15 extends between the first surface 11a of the board 11 and the semiconductor memory chip 14. The semiconductor memory chip 14 is electrically connected to the board 11 via the second bonding wire 15.

The electronic component 16 is a passive component like, for example, a capacitor or resistor. The electronic component 16 is mounted on the first surface 11a of the board 11 and electrically connected to the board 11.

The molding resin 17 (e.g., a molding resin portion, sealing portion, or sealing resin portion) is provided, for example, over substantially the entire region of the first surface 11a of the board 11. An example of the molding resin 17 is a resin (e.g., an epoxy resin). The molding resin 17 integrally covers (i.e., continuously covers) the controller chip 12, the first bonding wire 13, the semiconductor memory chip 14, a second bonding wire 15, and the electronic component 16.

As shown in FIG. 4, the molding resin 17 integrally includes a first region 21 (i.e., a first portion) covering the controller chip 12 and the first bonding wire 13 and a second region 22 (i.e., a second portion) covering the semiconductor memory chip 14 and the second bonding wire 15. That is, the first region 21 and the second region 22 are integrally formed and mutually connected.

The molding resin 17 has a groove 23 (i.e., a recess) to make the thickness of the molding resin 17 thinner provided between the first region 21 and the second region 22. The groove 23 extends in a direction crossing (e.g., substantially perpendicular to) the direction from the first region 21 toward the second region 22. A bottom 23a of the groove 23 does not reach the surface of the board 11. That is, the molding resin 17 is present between the bottom 23a of the groove 23 and the board 11. That is, a thin portion 24 (i.e., a third region or third portion) whose thickness is thin when compared with the first region 21 and the second region 22 is formed between the first region 21 and the second region 22 by the groove.

In the present embodiment, the first region 21 and the second region 22 are thermally divided by the groove 23. That “the first region 21 and the second region 22 are thermally divided” indicates that when compared with a case in which the first region 21 and the second region 22 are simply connected, less heat is transferred between the first region 21 and the second region 22. In the present embodiment, heat is less likely to be transferred between the first region 21 and the second region 22 by the groove 23.

As shown in FIG. 4, the molding resin 17 is not provided on the second surface 11b of the board 11. As shown in FIG. 3, the plurality of terminals 18 is provided on the second surface 11b of the board 11 and exposed to the outside of the board module 5. The plurality of terminals 18 is electrically connected to the controller chip 12. A wiring pattern connected to at least one (e.g., a power supply terminal) of the plurality of terminals 18 is electrically connected to the controller chip 12 and the semiconductor memory chip 14 by being branched at some midpoint. The housing 4 of the semiconductor device 1 has an opening that exposes the plurality of terminals 18 of the board module 5. The plurality of terminals 18 is exposed to the outside of the semiconductor device 1 through the opening of the housing 4 and can connect to a connector terminal of the external device 2. The semiconductor device 1 is electrically connected to the connector of the external device 2 via these terminals 18.

As shown in FIG. 3, the plurality of terminals 18 is substantially parallel to each other. The plurality of terminals 18 is arranged along an end of the board 11. The number of the plurality of terminals 18 and positions, intervals, and lengths thereof conform to the standard of the SD memory card.

A first direction X and a second direction Y are defined here. The first direction X is a direction along the second surface 11b of the board 11 in which the plurality of terminals 18 is arranged. The second direction Y is a direction along the second surface 11b of the board 11 and crossing (e.g., substantially perpendicular to) the first direction X.

As shown in FIG. 4, the board module 5 further includes a fuse 26. The fuse 26 is mounted on the first surface 11a of the board 11 and electrically connected to the board 11. The fuse 26 is electrically connected to at least one (e.g., a power supply terminal) of the plurality of terminals 18 between the controller chip 12 and the semiconductor memory chip 14.

When a current equal to or more than a predetermined current flows, an internal element of the fuse 26 melts and the electric connection between the terminals 18 and the controller chip 12 and the electric connection between the terminals 18 and the semiconductor memory chip 14 are cut off. Accordingly, the fuse 26 protects the semiconductor device 1 and the external device 2 to which the semiconductor device 1 is connected.

The fuse 26 may be positioned, for example, on the back side of the terminals 18. When compared with, for example, the controller chip 12, the fuse 26 is closer to at least one of the plurality of terminals 18. As shown in FIG. 4, the fuse 26 is provided in the second region 22 of the molding resin 17. Thus, the fuse 26 is less likely to be affected by heat from the controller chip 12.

As shown in FIG. 4, a thermal insulating portion 31 is provided around the fuse 26. The thermal insulating portion 31 is positioned inside the molding resin 17 (i.e., covered with the molding resin 17) and also covers the fuse 26.

The thermal insulating portion 31 is, for example, a thermal insulating sheet put on the fuse 26. The thermal insulating portion 31 covers the fuse 26 from the opposite side of the board 11 and also covers the fuse 26 from all directions, left, right, backward and forward. The thermal insulating portion 31 is positioned between the fuse 26 and the molding resin 17 to separate the fuse 26 from the molding resin 17. That is, the thermal insulating portion 31 inhibits heat from the fuse 26 from escaping to the molding resin 17.

Incidentally, the “thermal insulating portion 31” is not limited to one that completely blocks the transfer of heat between the fuse 26 and the molding resin 17 and may be a portion that decreases the transfer of heat between the fuse 26 and the molding resin 17 when compared with a case in which the fuse 26 and the molding resin 17 are in direct contact by having a thermal conductivity smaller than that of the molding resin 17. The thermal insulating portion 31 is not limited to the thermal insulating sheet and any material having high thermal insulating properties may be used regardless of the form thereof.

According to the semiconductor device 1 configured as described above, the improvement of reliability can be achieved.

With the increasing speed of electronic devices in recent years, processing capabilities demanded from the semiconductor device 1 also increase. The amount of heat produced of the controller chip 12 increases with increasing high-speed processing. In the case of the board module 5 of SiP type, the controller chip 12 and the semiconductor memory chip 14 are covered with the one molding resin 17 and thermally connected to each other via the molding resin 17. Thus, if the amount of heat produced by the controller chip 12 increases, the semiconductor memory chip 14 may fail.

Therefore, as countermeasures, managing the temperature of the controller chip 12 by the host apparatus and sending a directive to slow down the processing speed of the controller chip 12 from the host apparatus when the temperature of the controller chip 12 rises to a certain temperature or more can be considered. However, such countermeasures alone may not be able to cope with the speedup in the future because processing capabilities of the controller chip 12 are limited.

Thus, the semiconductor device according to the present embodiment includes a first component (e.g., the controller chip 12) that generates heat when used, a second component (e.g., the semiconductor memory chip 14), and a sealing portion (e.g., the molding resin 17). The sealing portion includes the first region 21 and the second region 22. The first region 21 covers the first component. The second region 22 is thermally divided from the second region 22 and covers the second component. According to the above configuration, heat from the first component is less likely to be transferred to the second component. Thus, the protection of the second component can be realized while permitting heat generation of the first component so that the improvement of reliability of the semiconductor device 1 can be achieved.

In the present embodiment, the semiconductor device 1 includes the board 11, the controller chip 12 on the board 11, the semiconductor memory chip 14 mounted on the board 11, the molding resin 17, and the plurality of terminals 18 provided on the board 11 and electrically connected to the controller chip 12. The molding resin 17 integrally includes the first region 21 covering the controller chip 12 and the second region 22 covering the semiconductor memory chip 14 and also the first region 21 and the second region 22 are thermally divided. According to the above configuration, heat from the controller chip 12 is less likely to be transferred to the semiconductor memory chip 14. Thus, the protection of the semiconductor memory chip 14 can be realized while permitting high-speed processing of the controller chip 12 so that the improvement of reliability of the semiconductor device 1 can be achieved.

In the present embodiment, the molding resin 17 has the groove 23 to make the thickness of the molding resin 17 thinner provided between the first region 21 and the second region 22. According to the above configuration, the first region 21 and the second region 22 can thermally be divided by a relatively simple structure.

Next, the effect of the thermal insulating portion 31 will be described. First, the semiconductor device 1 that does not have the thermal insulating portion 31 will be described for comparison. If the thermal insulating portion 31 is not included, the fuse 26 is directly covered with the molding resin 17 and is in contact with the molding resin 17. Thus, when the temperature of the fuse 26 rises with a current equal to or more than the predetermined current that flows to the fuser 26, heat escapes from the fuse 26 to the molding resin 17 and so it takes a long time before the fuse 26 melts.

If it takes a long time before the fuse 26 melts, the molding resin 17 may be carbonized and have conductivity in the meantime. Thus, there is a possibility of conduction maintained even after the fuse 26 melts via the carbonized molding resin 17.

Therefore, in the present embodiment, the semiconductor device 1 further includes the thermal insulating portion 31 provided around the fuse 26 and covering the fuse 26 inside the molding resin 17. According to the above configuration, when a current equal to or more than the predetermined current flows, heat generated in the fuse 26 can be inhibited from escaping to the molding resin 17. Therefore, the temperature rise time of the fuse 26 is shortened and the melting time of the fuse 26 is shortened. Accordingly, the fuse 26 operates within a predetermined time and also carbonization of the molding resin 17 is inhibited so that conduction can be prevented from being maintained via the molding resin 17. As a result, the protection of the semiconductor device 1 can reliably be achieved. Accordingly, reliability of the semiconductor device 1 can further be improved.

Next, semiconductor devices 1 according to the second to seventh embodiments will be described. The same reference numerals are attached to the same components as those in the first embodiment or components having similar functions and the description thereof is omitted. Components other than those described below are the same as in the first embodiment.

### Second Embodiment

Next, a semiconductor device 1 according to the second embodiment will be described with reference to FIG. 5. FIG. 5 is a diagram showing a board module 5 according to the present embodiment, (a) of FIG. 5 is a plan view thereof and (b) of FIG. 5 is a sectional view thereof. The semiconductor device 1 according to the present embodiment includes, instead of a groove 23 or in addition to a groove 23, a thermal insulating portion 41 (i.e., a second thermal insulating portion) between a first region 21 and a second region 22.

The thermal insulating portion 41 extends in a direction crossing (e.g., substantially perpendicular to) the direction from the first region 21 toward the second region 22. The thermal insulating portion 41 is provided, for example, inside a molding resin 17 and is covered with the molding resin 17. The thermal insulating portion 41 is a thermal insulating member mounted on a first surface 11a of a board 11. The thermal insulating portion 41 has a thermal conductivity smaller than that of the molding resin 17. Incidentally, any material having high thermal insulating properties may be used as the thermal insulating portion 41 regardless of the form thereof.

The thermal insulating portion 41 extends in a direction crossing (e.g., substantially perpendicular to) the direction from the first region 21 toward the second region 22. In the present embodiment, the first region 21 and the second region 22 are thermally divided by the thermal insulating portion 41. That is, heat is less likely to be transferred between the first region 21 and the second region 22 by the thermal insulating portion 41.

According to the above configuration, like the first embodiment described above, the improvement of reliability of the semiconductor device 1 can be achieved. In the third to seventh embodiments described below, the thermal insulating portion 41 may be provided instead of the groove 23 or in addition to the groove 23.

### Third Embodiment

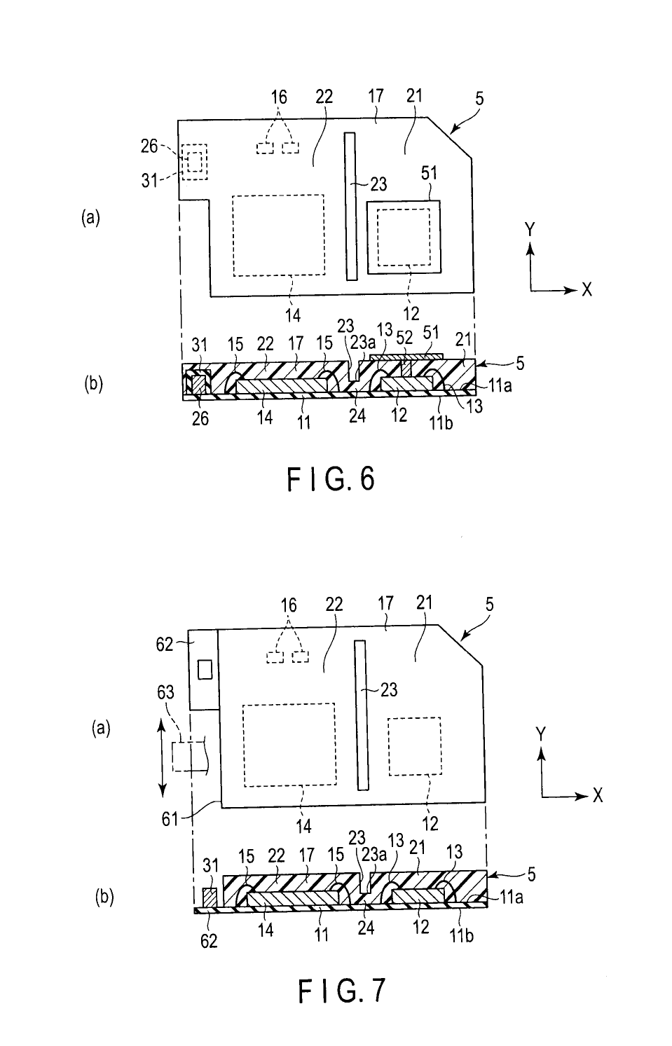

Next, a semiconductor device 1 according to the third embodiment will be described with reference to FIG. 6. FIG. 6 is a diagram showing a board module 5 according to the present embodiment, (a) of FIG. 6 is a plan view thereof and (b) of FIG. 6 is a sectional view thereof.

A semiconductor device 1 according to the present embodiment includes a metal portion 51 for heat radiation (i.e., a heat radiating portion). The metal portion 51 is, for example, a metal plate provided on the surface of a molding resin 17. The metal portion 51 is thermally connected to a controller chip 12 via, for example, a heat conductive member 52 (e.g., a metal component) embedded in the molding resin 17. A portion of heat of the controller chip 12 is escaped to the outside of the semiconductor device 1 from the metal portion 51.

According to the above configuration, like the first embodiment described above, the improvement of reliability of the semiconductor device 1 can be achieved. The semiconductor device 1 according to the present embodiment further includes the metal portion 51 provided on the surface of the molding resin 17 and thermally connected to the controller chip 12. Accordingly, heat radiation properties of the controller chip 12 are improved and further improvement of reliability of the semiconductor device 1 can be achieved.

### Fourth Embodiment

Next, a semiconductor device 1 according to the fourth embodiment will be described with reference to FIG. 7. FIG. 7 is a diagram showing a board module 5 according to the present embodiment, (a) of FIG. 7 is a plan view thereof and (b) of FIG. 7 is a sectional view thereof. In the semiconductor device 1 according to the present embodiment, a board 11 includes a portion 62 positioned outside a molding resin 17. A fuse 26 is provided in the portion 62 of the board 11 and is not covered with the molding resin 17.

More specifically, the board 11 includes a cut-out portion 61 and a protruding portion 62. The cut-out portion 61 is provided so as to avoid the range of movement of a switch 63 (e.g., a write protect switch). The position, range of movement and the like of the write protect switch conform to the standard of the SD memory card. The protruding portion 62 is formed by the cut-out portion 61. The protruding portion 62 protrudes from a side of the cut-out portion 61. The protruding portion 62 extends in a direction substantially parallel to a first surface 11a of a board 11. The protruding portion 62 extends in a direction in which a plurality of terminals 18 is arranged (i.e., a first direction X).

As shown in FIG. 7, the molding resin 17 is not provided in the protruding portion 62 of the board 11. The fuse 26 is mounted on the protruding portion 62 of the board 11 and is positioned outside the molding resin 17. That is, in the present embodiment, a structure in which the molding resin 17 is not sealed around the fused 26 is adopted.

According to the above configuration, like the first embodiment described above, the improvement of reliability of the semiconductor device 1 can be achieved. That is, in the present embodiment, the board 11 includes a portion (e.g., the protruding portion 62) positioned outside the molding resin 17. The fuse 26 is provided in the portion of the board 11 and is not covered with the molding resin 17.

Thus, when the temperature of the fuse 26 rises with a current equal to or more than the predetermined current that flows to the fuser 26, heat does not escape from the fuse 26 to the molding resin 17. In addition, the fuse 26 and the molding resin 17 are not in contact and thus, the molding resin 17 is prevented from being carbonized. Accordingly, the fuse 26 operates within a predetermined time and also carbonization of the molding resin 17 is inhibited so that conduction can be prevented from being maintained via the molding resin 17.

In the present embodiment, the board 11 includes the protruding portion 62 outside the molding resin 17. The fuse 26 is provided on the protruding portion 62 of the board 11. Even when the molding resin 17 is provided in the substantially entire surface of the board 11, the protruding portion 62 can easily be secured as a region that is not sealed with the molding resin 17. Incidentally, the mounting position of the fuse 26 is not limited to the protruding portion 62. The fuse 26 may be mounted in the center of the board 11 and also the region may not be sealed with the molding resin 17.

In the fifth to seventh embodiments described later, instead of providing a thermal insulating portion 31, the fuse 26 may be mounted on a region that is not sealed with the molding resin 17.

### Fifth Embodiment

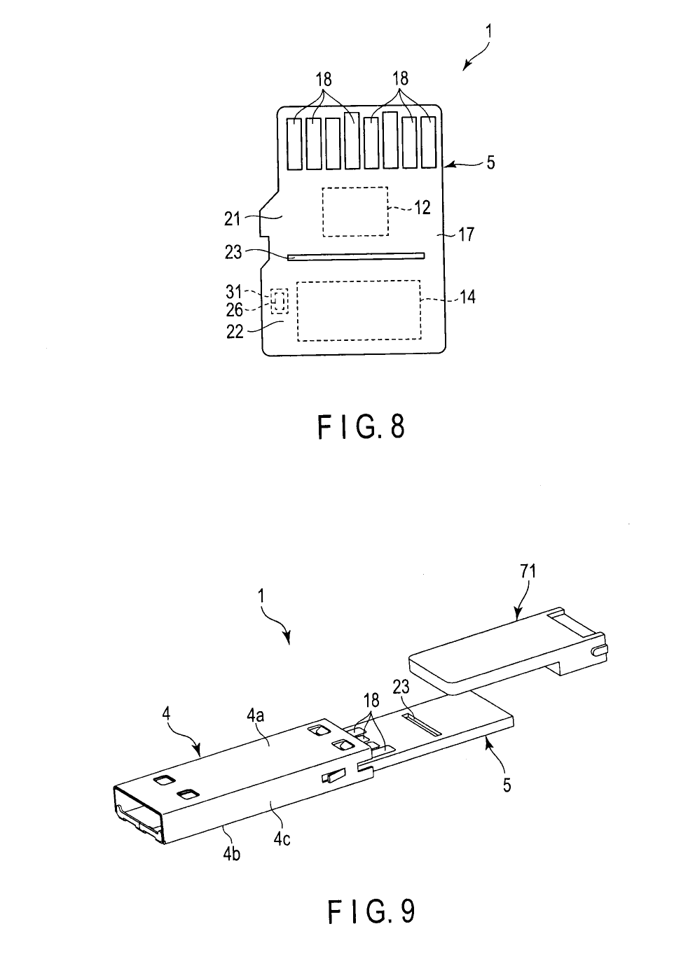

Next, a semiconductor device 1 according to the fifth embodiment will be described with reference to FIG. 8. FIG. 8 shows a plan view of the semiconductor device 1 according to the present embodiment. The semiconductor device 1 according to the present embodiment is a Micro SD card (trademark). The semiconductor device 1 according to the present embodiment does not have a housing 4 and a molding resin 17 forms an outer hull of the semiconductor device 1. That is, the semiconductor device 1 according to the present embodiment is configured by a board module 5.

According to the above configuration, like the first embodiment described above, the improvement of reliability of the semiconductor device 1 can be achieved.

### Sixth Embodiment

Next, a semiconductor device 1 according to the sixth embodiment will be described with reference to

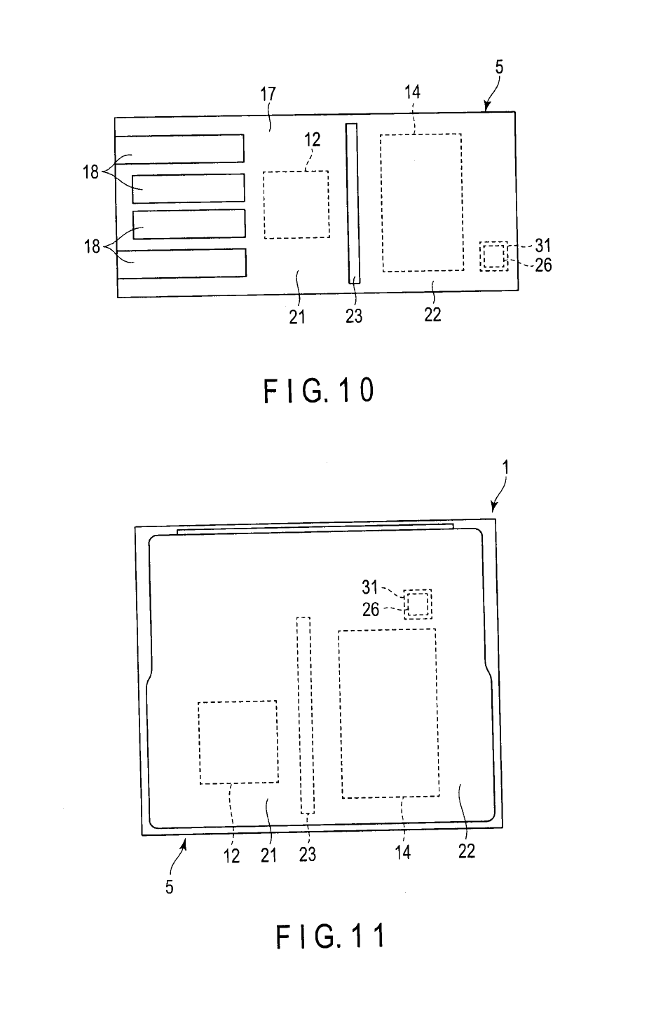

FIGS. 9 and 10. FIG. 9 is a perspective view partially exploding and showing the semiconductor device 1 according to the present embodiment. FIG. 10 is a plan view illustrating a board module 5 shown in FIG. 9.

The semiconductor device 1 according to the present embodiment is a USB memory. The semiconductor device 1 according to the present embodiment includes a housing 4, the board module 5 accommodated in the housing 4, and a stopper 71 (i.e., a holder) that holds the board module 5 inside the housing 4.

According to the above configuration, like the first embodiment described above, the improvement of reliability of the semiconductor device 1 can be achieved. Incidentally, the semiconductor device 1 may be a USB memory configured by the board module 5 without the housing 4.

### Seventh Embodiment

Next, a semiconductor device 1 according to the seventh embodiment will be described with reference to FIG. 11. FIG. 11 shows a plan view of the semiconductor device 1 according to the present embodiment. The semiconductor device 1 according to the present embodiment is a Compact Flash (trademark). The semiconductor device 1 according to the present embodiment includes a housing 4 and a board module 5 accommodated in the housing 4.

According to the above configuration, like the first embodiment described above, the improvement of reliability of the semiconductor device 1 can be achieved.

The present invention is not limited to the above first to seventh embodiments. Components according to each embodiment can appropriately be exchanged or combined to carry out an embodiment. The structure to thermally separate the first region 21 and the second region 22 is not limited to the groove 23 and the thermal insulating portion 41 and other structures may also be adopted.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a board comprising a first surface and a second surface opposite to the first surface;
a controller chip on the first surface of the board;
a first bonding wire between the first surface of the board and the controller chip;
a semiconductor memory chip on the first surface of the board;
a second bonding wire between the first surface of the board and the semiconductor memory chip;
a molding resin on the first surface of the board, the molding resin integrally comprising a first region, a second region, and a groove, the first region covering the controller chip and the first bonding wire, the second region covering the semiconductor memory chip and the second bonding wire, the groove located between the first region and the second region and making a thickness of the molding resin thinner; and
terminals on the second surface of the board, the terminals electrically connected to the controller chip and connectable to a connector of an external device.

2. The device of claim 1, further comprising:
a fuse electrically connected between at least one of the terminals and the controller chip.

3. The device of claim 2, further comprising:
a thermal insulating portion covering the fuse inside the molding resin.

4. The device of claim 2, wherein
the board comprises a portion located outside the molding resin, and
the fuse is on the portion of the board.

5. The device of claim 2, wherein
the fuse is in the second region of the molding resin.

6. A semiconductor device comprising:
a board;
a controller chip on the board;
a semiconductor memory chip on the board;
a molding resin on the board, the molding resin integrally comprising a first region and a second region, the first region covering the controller chip, the second region thermally divided from the first region and covering the semiconductor memory chip; and
terminals on the board, the terminals electrically connected to the controller chip.

7. The device of claim 6, wherein
the molding resin comprises a groove between the first region and the second region, the groove making a thickness of the molding resin thinner.

8. The device of claim 6, further comprising:
a fuse electrically connected between at least one of the terminals and the controller chip.

9. The device of claim 8, further comprising:
a thermal insulating portion covering the fuse inside the molding resin.

10. The device of claim 8, wherein
the board comprises a portion located outside the molding resin, and
the fuse is on the portion of the board.

11. The device of claim 6, further comprising
a metal portion on a surface of the molding resin, the metal portion thermally connected to the controller chip.

12. A semiconductor device comprising:
a first component that generates heat when used;
a second component; and
a sealing portion comprising a first region and a second region, the first region covering the first component, the second region thermally divided from the first region and covering the second component.
